(19) United States
(12) Patent Application Publication
(10) Pub. No.: US 2019/0103365 A1
(43) Pub. Date: Apr. 4, 2019

(54) SELECTIVELY SHIELDED SEMICONDUCTOR PACKAGE

(71) Applicant: NXP USA, Inc., Austin, TX (US)

(72) Inventors: Akhilesh Kumar SINGH, Austin, TX (US); Nishant Lakhera, Austin, TX (US); Navas Khan Oratti Kalandar, Austin, TX (US)

(21) Appl. No.: 15/719,668

(22) Filed: Sep. 29, 2017

(51) Int. Cl. H01L 23/552; H01L 23/31; H01L 23/66; H01L 23/498

(52) U.S. Cl. CPC H01L 23/552; H01L 23/3121; H01L 2223/6677; H01L 23/49811; H01L 23/66

(57) ABSTRACT

Embodiments for a packaged semiconductor device are provided herein, which includes a substrate; an antenna module attached to a top surface of the substrate, the antenna module including an antenna; an electronic component attached to the top surface of the substrate, the electronic component communicatively coupled to the antenna module through electrical connections in the substrate; a first portion of mold body that encapsulates the antenna module; a second portion of mold body that encapsulates the electronic component, wherein the second portion of mold body is separated from the first portion of mold body by at least a first trench; and a shielding layer that covers the second portion of mold body.

### BACKGROUND

### Field

This disclosure relates generally to semiconductor packages, and more specifically, to semiconductor packages having shielding in selective locations.

### Related Art

Electromagnetic interference is disruptive electromagnetic energy generated by electromagnetic induction, electrostatic coupling, or conduction that affects the operation of electrical circuitry. For example, an antenna receives and generates radio frequency (RF) fields, which may generate disruptive electromagnetic energy in a neighboring circuit. If the circuit is not shielded or isolated from the antenna, the disruptive electromagnetic energy may degrade performance of the circuit.

### BRIEF DESCRIPTION OF THE DRAWINGS

The present invention may be better understood, and its numerous objects, features, and advantages made apparent to those skilled in the art by referencing the accompanying drawings.

FIGS. 1A, 1B, 2A, 2B, 3A, 3B, 3C, 3D, 4A, 4B, 4C, 4D, 5A, 5B, 6A, and 6B illustrate block diagrams depicting example packaged semiconductor devices in which the present disclosure is implemented, according to some embodiments.

FIGS. 7, 8, 9, 10, 11, 12A, 12B, 13A, 13B, 13C, 14A, 14B, 15A, and 15B illustrate block diagrams depicting steps for fabricating a packaged semiconductor device in which the present disclosure is implemented, according to some embodiments.

The present invention is illustrated by way of example and is not limited by the accompanying figures, in which like references indicate similar elements, unless otherwise noted. Elements in the figures are illustrated for simplicity and clarity and have not necessarily been drawn to scale.

### DETAILED DESCRIPTION

The following sets forth a detailed description of various embodiments intended to be illustrative of the invention and should not be taken to be limiting.

### Overview

A common problem experienced by wireless communication systems is electromagnetic interference, which may degrade performance. A system-in-package (SIP) with an embedded antenna requires a signal barrier to reduce interference from the antenna to the rest of the SIP components. While some SIP designs include a metal lid to form such a barrier, the mold tooling that embeds the metal lid into the package may press onto the metal lid and cause it to tilt, which creates uneven contact with the substrate and forms an opening or aperture between the substrate and the uneven frame, resulting in poor shielding. Similarly, the frame of the metal lid may be warped or otherwise does not sit flat on the substrate, which also creates uneven contact with the substrate. The presence of the metal lid may also increase costs of fabricating the SIP, due to fabrication of the metal lid itself and mounting the lid to the substrate of the SIP.

The present disclosure provides embodiments of a packaged semiconductor device that provides an improved signal barrier between an embedded antenna and embedded electronic components. The present disclosure provides for creating a conductive trace along the top surface of the package substrate between the antenna and the electronic components, where the conductive trace has even conformal contact with the package substrate. The conductive trace also makes electrical contact with at least one ground pad on the package substrate. A mold body is formed to embed the electronic components and antenna, and a trench is formed to expose the conductive trace and separate the mold body into two or more portions, one of which includes the antenna. A conductive shielding layer is selectively deposited on the mold body portions that include the electronic components, including in the trench to contact the exposed conductive trace. Each mold body portion is effectively sealed with the conductive shielding layer formed over the portion's top surface and down each side wall of the portion, which forms one or more shielded compartments without any apertures or openings along the surface of the package substrate. The mold body portion that includes the antenna remains unshielded. The shielded compartments isolate the electronic components from the antenna, as well as from the external environment, minimizing the electromagnetic fields (such as radio frequency fields) experienced by the electronic components within the shielded compartments. The shielded compartments also prevent the embedded electronic components from radiating electromagnetic interference into the surrounding environment, which further isolates an electronic component from other electronic components in a neighboring shielded compartment. Optionally, a ground plane may also be included in the package substrate underneath each shielded compartment to provide additional shielding, which may or may not make electrical contact with the shielded layer that covers external side walls of the shielded compartment.

### Example Embodiments

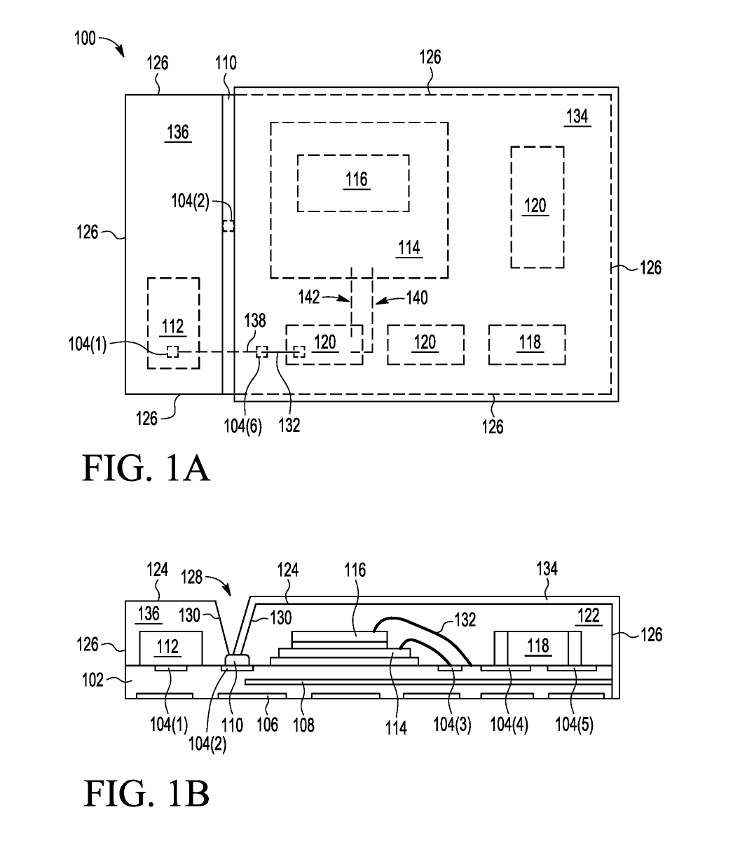

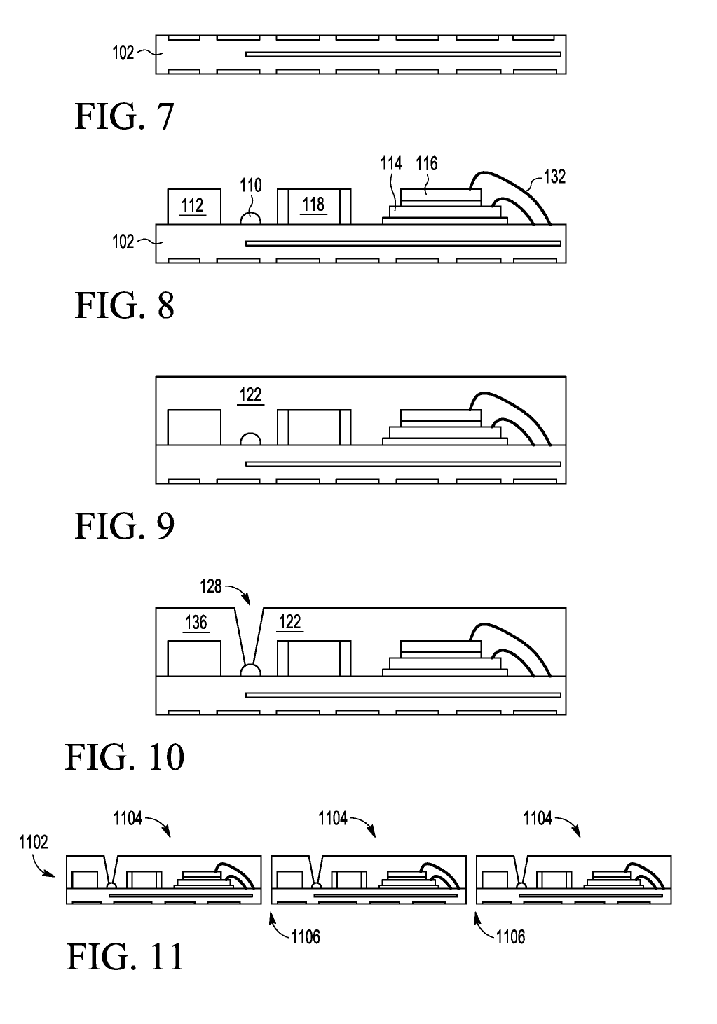

FIG. 1A shows a plan view, and FIG. 1B shows a representative cross-sectional view, of an example packaged semiconductor device 100 (also referred to as a package 100) having selective shielding according to the present disclosure. It is noted that the single substrate 102 shown in FIG. 1B and in the remaining figures may be representative of a number of substrates formed as part of an array or strip of substrates that are singulated to form a number of packages. A fabrication process for forming a packaged semiconductor device (e.g., as shown in FIGS. 1A and 1B) according to the present disclosure is discussed below beginning with FIG.7. While FIG. 1A and each of the remaining figures show a particular combination of electronic components and shielded compartments, other embodiments may include any combination of electronic components with any combination of shielded compartments.

Package 100 includes a package substrate 102 having a plurality of pads on a top surface of the package substrate, referred to as top substrate pads 104, and a plurality of pads on a bottom surface of the package substrate, referred to as bottom substrate pads 106. In some embodiments, package substrate 102 is made of a number of dielectric material layers and conductive material layers to form conductive structures through the substrate 102, which include plating, pads (e.g., pads 104 and 106), interconnects, and vias. Such conductive structures are formed from an electrically conductive material, examples of which include but are not limited to nickel, gold, copper, aluminum, or other suitable conductive metal or alloy composed of one or more suitable conductive metals. The top and bottom substrate pads 104 and 106 on the package substrate 102 may be coated with an electrically conductive material, examples of which include nickel, gold, copper, aluminum, tin, silver, titanium, or other suitable conductive metal or alloy composed of one or more suitable conductive metals in order to improve the “bondable” nature of the pad. Examples of a package substrate include, but are not limited to, a ball grid array (BGA), a pin grid array (PGA), and the like.

Package substrate 102 also includes a number of electronic components attached to the top surface of the package substrate 102, where each electronic component has one or more pads or pins or other connection surface that are electrically connected to respective top substrate pads 104. The various combinations of electronic components that may be attached to a package substrate are represented by a few example combinations shown in the remaining figures, where any number of combinations of these electronic components may be implemented in a package. For example, the embodiment shown includes an antenna module 112, a first die 114, a second die 116, and a surface mounted device (SMD) 118 attached and electrically connected to top substrate pads 104 of substrate 102. One or more other electronic components may also be attached and electrically connected to top substrate pads 104, as represented by electronic components 120. Examples of electronic components include but are not limited to a passive device, such as a relay, a resistor, an inductor, a capacitor, a diode, a power transistor, an oscillator, and the like, other types of electronic devices, and a semiconductor device, such as a semiconductor die, which may be a wirebondable semiconductor die (e.g., having pads to which wirebonds are connected) or a flip chip semiconductor die (e.g., having pads to which solder bumps are connected).

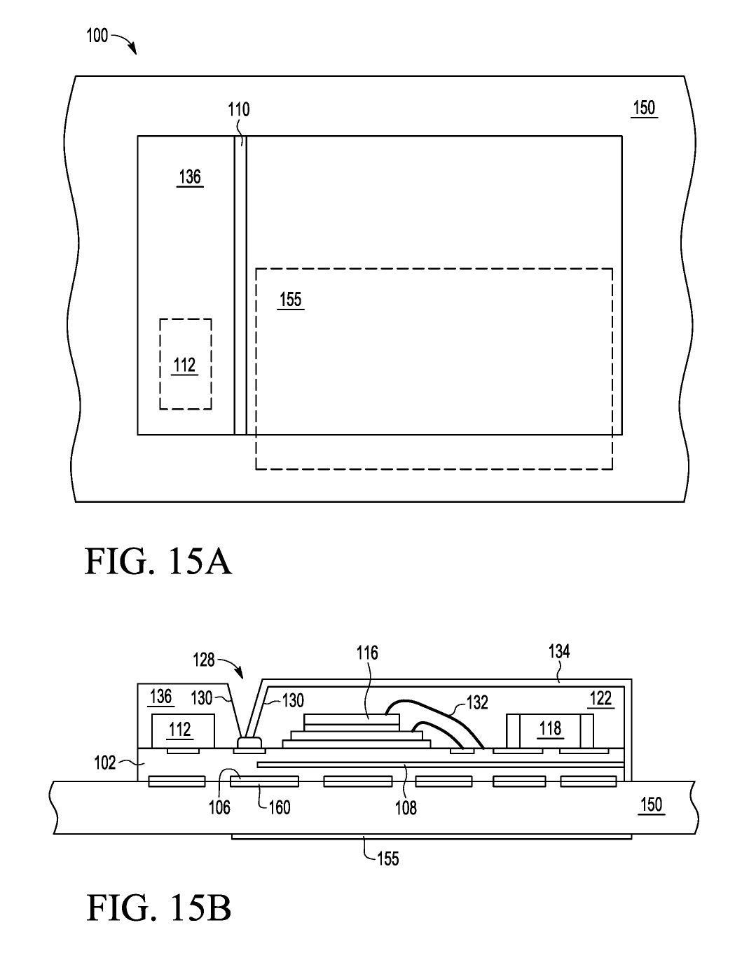

The conductive structures of the package substrate 102 provide connection paths (or electrically conductive paths), which may be internal connections between electronic components respectively connected to top substrate pads 104 (e.g., between antenna module 112 and die 114) or may be external connections from the electronic components to external conductive package structures, such as solder balls connected to the bottom substrate pads 106, and the like. In some embodiments, the package 100 may be attached and electrically connected to an underlying printed circuit board (PCB) by a plurality of solder balls or solder paste that electrically connect the bottom substrate pads 106 to respective landing pads on the PCB. As shown in FIG. 15B, package 100 is mounted to PCB 150 as a land grid array (LGA) configuration with solder paste, although solder balls may be used in other embodiments. A PCB includes electrically conductive features on a non-conductive substrate, which may be a flexible type PCB using polyimide or a rigid type PCB using FR4 or BT resin.

Antenna module 112 includes at least one antenna for wireless communication, such as radio frequency (RF) communication. For example, antenna module 112 may include a dedicated transmitting antenna and a dedicated receiving antenna in some embodiments, while in other embodiments, antenna module 112 may include a single antenna configured to function as both the transmitting antenna and the receiving antenna (e.g., a circulator or other coupling device would also be needed to connect transmitter output to the antenna during a transmission phase and to connect the antenna to receiver input during a receive phase). In some embodiments, antenna module 112 is a chip antenna, which is a passive surface mount device (SMD) having an antenna included in a ceramic body that has high permittivity and low loss. In some embodiments, a chip antenna may include a quarter-wave element and uses a ground plane in an underlying PCB as a counterpoise to form a half-wave dipole, as also shown as ground plane 155 in FIGS. 15A and 15B. Examples of the at least one antenna of antenna module 112 include but are not limited to a patch antenna, a microstrip antenna, a helical antenna, a loop antenna, a monopole antenna, and the like.

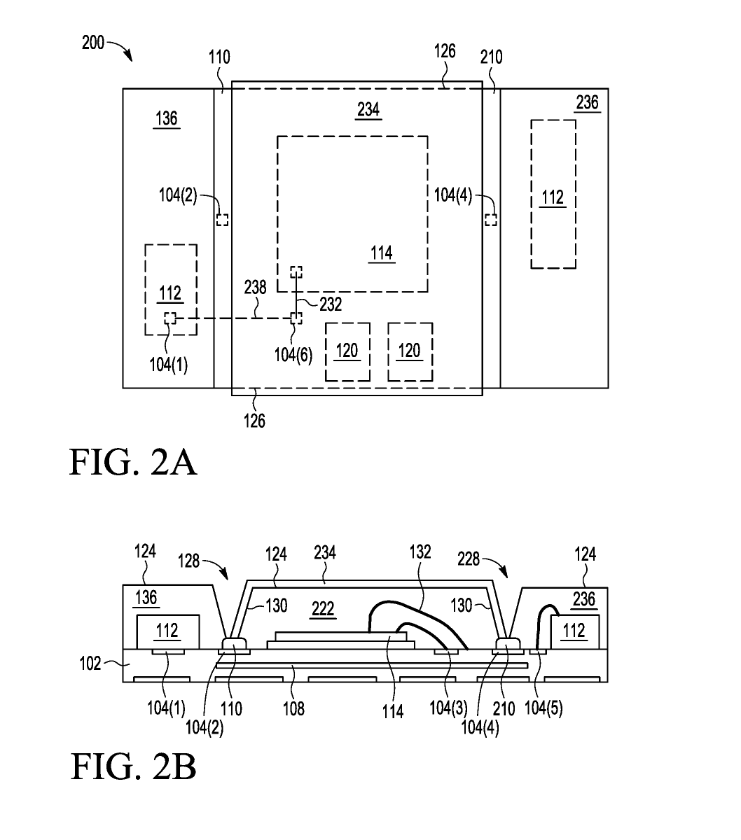

Antenna module 112 includes at least one pin connected to a top substrate pad 104, which in turn is connected to a feed line or transmission line 138 implemented in the substrate 102. In the embodiment shown, antenna module 112 has a pin connected to pad 104(1) that in turn is connected to a conductive path 138 through the substrate 102 (e.g., covered by one or more layers of dielectric material of the substrate 102) to another pad 104(6) that in turn is connected to a pad of electronic component 120 by a wirebond 132. In the embodiment shown, the electronic component 120 includes a radio frequency (RF) front end, or RF transmitter and receiver respectively configured to transmit and receive RF signals. The RF front end component 120 may be implemented as an integrated circuit (IC) or IC die that includes front end components of the RF transmitter and receiver (e.g., a transmitter power amplifier, a receiver low noise amplifier, one or more baluns, one or more filters, a circulator or other coupling device, impedance matching elements, and other appropriate front end elements). In such embodiments, the RF front end component 120 is also communicatively connected to a semiconductor die (e.g., die 114 or 116) that includes functionality for processing the transmitted and received RF signals (e.g., includes circuitry that implements digital signal processing). In the embodiment shown, RF front end component 120 is communicatively connected by transmit and receive paths 140 and 142 to die 114, each of which may be implemented with another conductive path 138 through substrate 102 with a pad 104 on either end, and wirebonds 132 between pads 104 and the pads of the respective component 120 and die 114. In other embodiments, the RF front end components may be implemented as part of a semiconductor die (e.g., die 114 or 116), which also includes functionality for processing the transmitted and received RF signals (e.g., circuitry that implements digital signal processing), which is shown in FIG. 2A as antenna module 112 being communicatively connected to die 114 by feed line 238.

Die 114 is a semiconductor die that has a back side attached to the top surface of the substrate 102 and a front side in a face-up orientation. The front side of die 114 includes active circuitry and a number of pads. In the embodiment shown, the front side of die 114 also includes an attachment area in which a back side of die 116 is attached to the front side of die 114, where die 116 has a footprint or perimeter that is smaller than the footprint or perimeter of underlying die 114. Die 116 is a semiconductor die that also includes active circuitry and a number of pads on a front side that is also in a face-up orientation. Die 114 and die 116 are referred to herein as wirebondable die since their bond pads are capable of withstanding thermosonic forces during wire bonding. The pads of wirebondable die 114 and 116 are electrically connected to respective pads 104 on the substrate 102 by a number of wirebond connections 132. Die 114 and die 116 are attached using a suitable die attach material. Examples of die attach material include but are not limited to polymer adhesives, epoxies, solders, pastes, films, tailored die cut tapes, and the like.

A semiconductor die (e.g., die 114 and 116) may be singulated from a semiconductor wafer, which can be any semiconductor material or combinations of materials, such as gallium arsenide, silicon germanium, silicon-on-insulator (SOI), silicon, monocrystalline silicon, the like, and combinations of the above. Such a semiconductor die includes active circuitry, which may include integrated circuit components that are active when the die is powered. The active circuitry is formed on the semiconductor wafer using a sequence of numerous process steps applied to semiconductor wafer, including but not limited to depositing semiconductor materials including dielectric materials and metals, such as growing, oxidizing, sputtering, and conformal depositing, etching semiconductor materials, such as using a wet etchant or a dry etchant, planarizing semiconductor materials, such as performing chemical mechanical polishing or planarization, performing photolithography for patterning, including depositing and removing photolithography masks or other photoresist materials, ion implantation, annealing, and the like. In some embodiments, the active circuitry may be a combination of integrated circuit components or may be another type of microelectronic device. Examples of integrated circuit components include but are not limited to a processor, memory, logic, oscillator, analog circuitry, sensor, MEMS (microelectromechanical systems) device, a standalone discrete device such as a resistor, inductor, capacitor, diode, power transistor, and the like.

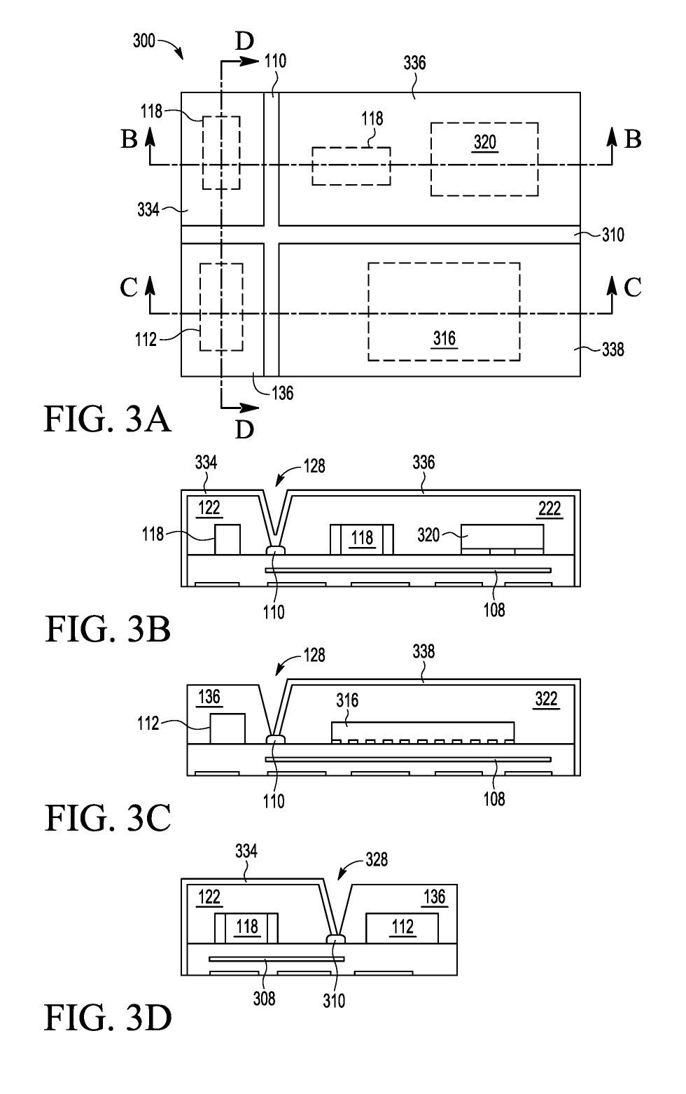

It is noted that die 114 and 116 are representative of various types of electronic components that may be attached to the top surface of substrate 102 in a face-up orientation, where such electronic components have pads electrically connected to top substrate pads 104 by wirebond connections 132 (e.g., pad 104(3) and wirebond 132 are representative of such connections). As another example, SMD 118 is representative of various types of surface mounted electronic components that may be attached and electrically connected to the top substrate pads 104 of substrate 102 (e.g., SMD 118 has two pins that are attached and electrically connected to respective pads 104(4) and 104(5), as shown in FIG. 1B). Another example includes a flip chip die 316 shown in FIGS. 3A and 3C, which is representative of various types of electronic components that may be attached and electrically connected to the top surface of substrate 102 in a face-down orientation, where such electronic components have pins or solder bumps attached and electrically connected to top substrate pads 104.

Conductive trace 110 is an exposed trace (e.g., not covered with dielectric material) on the top surface of package substrate 102. The conductive trace 110 is formed from an electrically conductive material, examples of which include but are not limited to nickel, gold, copper, aluminum, or other suitable conductive metal or alloy composed of one or more suitable conductive metals. Conductive trace 110 is formed in an area between antenna module 112 and the other electronic components 114, 116, 118, and 120, where the other electronic components are laterally separated from antenna module 112. Conductive trace 110 is to directly contact at least one top substrate pad that is connected to ground, such as pad 104(2), to make electrical contact with ground. In other embodiments, conductive trace 110 may be formed to directly contact multiple ground pads. Conductive trace 110 follows a target path along which a shielding side wall is formed, as further discussed below. In the embodiment shown in FIGS. 1A and 1B, conductive trace 110 forms a single straight line from one side of substrate 102 to an opposing side of substrate 102, although conductive trace 110 may be formed in any other suitable shaped path, such as paths that include curved lines, angled lines, or one or more lines that form a closed loop path, where such lines or paths may be formed from edge-to-edge of substrate 102 (e.g., a path between opposite edges or between an edge and one of its perpendicular edges) or may be located within an outer perimeter of the package substrate without reaching an edge. In some embodiments, conductive trace 110 may have a much taller height than the height of a traditional metal trace formed on the package substrate 102. In some embodiments, conductive trace 110 may be formed as part of substrate 102 as an exposed metal layer (e.g., not covered with a dielectric layer). In some embodiments, conductive trace 110 may be formed using a conductive ink that is printed or otherwise deposited on the substrate 102 and then sintered (e.g., by a laser beam or by temperature excursion). In some embodiments, conductive trace 110 may be formed using a conductive epoxy that is printed or otherwise deposited in the desired shape or path and then hardened (e.g., by temperature excursion or UV (ultraviolet light) exposure).

A first portion of mold body 136 surrounds and encapsulates the antenna module 112 and a second portion of mold body 122 surrounds and encapsulates the remaining electronic components to be shielded, such as components 114, 116, 118, and 120. It is noted that no other electronic components are located with the antenna module 112 in mold body portion 136. Mold body portions 122 and 136 each have a top surface 124 that are substantially coplanar with one another and each have exterior side walls 126 (e.g., outward-facing side walls of the mold body) that are also substantially aligned with outer edges of the package substrate 102. Side walls 126 may also be viewed as being located on (or aligned with) an outer perimeter of the package substrate 102. Mold body portions 122 and 136 are laterally separated from one another by a trench 128 in which a top surface of the conductive trace 110 is exposed. Trench 128 forms opposing or neighboring interior side walls 130 (e.g., side walls that are not outward-facing) of the mold body portions 122 and 136, also referred to as trench side walls 130. Side walls 130 may also be viewed as being located within the outer perimeter of the package substrate 102.

In some embodiments, mold body portions (e.g., portions 122 and 136) may be formed from a single mold body that may be formed using an encapsulating method, such as overmolding, transfer molding, or other type of encapsulating method, which is separated into two or more portions that are entirely physically separate and distinct from one another by forming one or more trenches 128 in the mold body using a cutting technique, such as sawing, etching, laser cutting, and the like. In other embodiments, the mold body portions may be directly formed using film assisted molding that uses a plunger member directly over the conductive trace 110 to expose it without cutting a trench into the mold body. In some embodiments, a mold body or mold body portion is made of an encapsulant material such as a mold compound based on a biphenyl type or multi-aromatic type epoxy resin, but may be other types of encapsulating materials in other embodiments. Other embodiments that implement a different number of trenches that follow differently shaped paths are further discussed below.

Depending upon the technique used to form the trench 128, the side walls 130 formed by trench 128 may be separated from one another by a first distance at the top of the trench 128 (e.g., at the top surface 124 of the mold body portions 122 and 136) that is greater than a second distance at the bottom of the trench 128 (e.g., at the exposed surface of the conductive trace 110), which form outward sloping side walls 130. For example, a trench 128 that is cut by a saw blade may form side walls 130 that are separated by 50 microns at the top of the trench 128, which narrows as the trench 128 reaches the conductive trace 110. As a result, such side walls 130 slope outward in a range of up to 30 degrees (e.g., 0 degrees measured on the vertical), such as in a preferred range of 15 to 20 degrees. The angle or slope of the side walls 130 should be enough to ensure conformal coating of the conductive shielding layer along the side wall 130 down to the conductive trace 110, where the shielding layer 134 directly contacts the conductive trace 110 to make electrical contact, as discussed below.

Conductive shielding layer 134 is selectively formed over the mold body portion 122 that includes electronic components 114, 116, 118, and 120, which may also be referred to as a shielded compartment. Shielding layer 134 is configured to shield and isolate those components by both blocking any electromagnetic radiation from the surrounding environment that may degrade performance of those components and by blocking any emissions from the electronic components themselves. The mold body portion 136 that includes antenna module 112 remains unshielded. The shielding layer 134 is formed from an electrically conductive material, examples of which include but are not limited to nickel, gold, copper, aluminum, silver, or other suitable conductive metal or alloy composed of one or more suitable conductive metals. The shielding layer 134 may be formed by sputtering or otherwise depositing a conductive material over the mold body portion 122, where the conductive material blocks RF fields from passing through the shielding layer 134, which may be an externally generated RF field or an internally generated RF field. The effectiveness of the conductive shielding layer 134 depends upon conductivity of the material used, the permeability of the material used, and the thickness of the material used.

In the embodiment shown, shielding layer 134 is conformally formed (and makes direct contact) over the top surface 124 of mold body portion 122, over the inner side wall 130 of mold body portion 122 down to conductive trace 110, and over the exterior side walls 126 of mold body portion 122. Shielding layer 134 makes electrical contact with conductive trace 110, which in turn makes electrical contact with at least one ground pad, enabling shielding layer 134 to provide a grounded shielded compartment to isolate any electronic components embedded within mold body portion 122. While shielding layer 134 extends down to entirely cover the side walls of the package substrate 102 in the embodiment shown, shielding layer 134 may only extend down to cover the exterior side walls 126 of the mold body portion 122 in other embodiments. It is also noted that in the embodiment shown in FIG. 1A, shielding layer 134 has some thickness as it extends over side walls 126 (shown as dashed interior sides underlying shielding layer 134) of the mold body portion 122. In the remaining embodiments, the shielding layer 134 has a similar thickness, but is not distinguished from side walls 126 for simplicity's sake.

Ground plane 108 may also be implemented at some level or layer within the package substrate 102, in some embodiments. For example, ground plane 108 is a substantial portion of a metal layer within substrate 102, which may have a minimal number of holes or apertures through which electrical conductive paths from the internal components to external connections are made. Ground plane 108 is located directly underneath the electronic components attached to the top surface of the package substrate 102 and provides additional shielding beneath the electronic components. Ground plane 108 is laterally separated from antenna module 112 by a keep out area (e.g., an edge of ground plane 108 is laterally separated from the footprint or perimeter of antenna module 112, and is not located directly underneath antenna module 112 to avoid any distortion in the radiation of the antenna) and extends away from antenna module 112. In the embodiment shown, ground plane 108 extends to the outer edges of the package substrate 108 and makes electrical contact with the shielding layer 134 in order to provide another ground contact for the shielding layer 134. It is also noted that the keep out area may affect the placement of the bottom substrate pads 106, which presently are shown in the figures being distributed in a uniform pitch across the bottom surface of package substrate 102, which is representative of general pad placement. For example, while FIG. 1B shows a bottom substrate pad 106 underneath antenna module 112, other embodiments may remove such substrate pads 106 from underneath antenna module 112 in order to avoid distortion of the signals at antenna module 112.

It is noted that such a ground plane 108 is preferred in embodiments where antenna module 112 is a chip antenna, which may be coupled to another ground plane in the underlying PCB that acts as a counterpoise to a quarter-wave antenna in antenna module 112 to form a half-wave dipole antenna. In such embodiments, ground plane 108 provides further shielding for components 114, 116, 118, and 120 from additional interference that may be generated due to the underlying counterpoise, as shown in FIGS. 15A and 15B. FIG. 15A shows a top-down view, and FIG. 15B shows a representative cross-sectional view, of the package 100 attached to a top surface of PCB 150, with a ground plane 155 that acts as a counterpoise on the bottom surface of PCB 150. The ground plane 155 also remains outside of the keep out area that laterally surrounds antenna module 112. FIG. 15B also shows the bottom substrate pads 106 of the package 100 attached to respective landing pads 160 of PCB 150. The radiation pattern and tuning of the PCB counterpoise 155 is based on the size and shape of the PCB counterpoise 155, as well as the orientation and location of antenna module 112 relative to the PCB counterpoise 155. Other embodiments of the example packages described herein may be attached to a PCB 150 like that shown in FIGS. 15A and 15B, which may or may not implement the PCB ground plane 155, depending on whether a counterpoise is required. Also, other embodiments of the example packages described herein may or may not implement the ground plane 108, depending on the isolation and shielding requirements of the package.

FIG. 2A shows a plan view, and FIG. 2B shows a representative cross-sectional view, of another example packaged semiconductor device 200 (or package 200) having selective shielding to form a center shielded compartment while antenna modules near the outer edges of the package 200 remain unshielded. It is noted that the packages described herein are shown having various combinations of the electronic components described above, which are denoted with reference numbers having at least the same last two digits.

As shown in FIG. 2A, package 200 includes two antenna modules 112, one on the left side and the other on the right side of package 200. In the embodiment shown, die 114 includes both an RF front end and circuitry that implements digital signal processing, where the left antenna module 112 is communicatively connected to die 114 by feed line 238 having a pad 104(1) and 104(6) on either end, and wirebond 232 connected between pad 104(6) and a pad of the die 114. The right antenna module 112 is representative of another type of antenna module that may include a pad that is wirebonded to a top substrate pad 104(5). The pad 104(5) is connected to a feed line that communicatively connects the right antenna module 112 to die 114 in some embodiments, or connects to an RF front end component 120 in other embodiments.

Left antenna module 112 is encapsulated in a first or left mold body portion 136, right antenna module 112 is encapsulated in a second or right mold body portion 236, and the remaining electronic components to be shielded are encapsulated in a third or center mold body portion 222 positioned between the left and right mold body portions 136 and 236. In the embodiment shown, conductive traces 110 and 210 are formed in parallel straight lines that both extend from one edge to an opposite edge of the package substrate 102. Conductive trace 110 is connected to at least one ground pad 104(2) and conductive trace 210 is connected to at least one ground pad 104(4). A first trench 128 separates the left mold body portion 136 from the center mold body portion 222 by forming neighboring interior side walls 130 of portions 136 and 222, which also exposes a top surface of conductive trace 110. A second trench 228 separates the right mold body portion 236 from the center mold body portion 222 by similarly forming neighboring interior side walls 130 of portions 222 and 236, which also exposes a top surface of conductive trace 210. A shielding layer 234 is formed over a top surface 124, interior side walls 130, and exterior side walls 126 of the center mold body portion 222 to form a shielded compartment that isolates the electronic components 114 and 120. Mold body portions 136 and 236 that each include an antenna module 112 remain unshielded. In the embodiment shown, a ground plane 108 is also implemented to provide shielding underneath mold body portion 222, but may not be implemented in the package 200 in other embodiments.

FIG. 3A shows a plan view, and FIGS. 3B, 3C, and 3D show representative cross-sectional views, of another example packaged semiconductor device 300 (or package 300) having selective shielding to form three shielded compartments with an antenna module near an outer edge of the package 300 remaining unshielded. Package 300 includes four mold body portions 136, 122, 222, and 322 that are separated from one another by two trenches that follow and expose perpendicular conductive traces. As shown in FIG. 3A, conductive trace 110 extends from a first edge to an opposite second edge of the package substrate 102, and conductive trace 310 extends from a third edge to an opposite fourth edge of the package substrate 102. Conductive traces 110 and 310 are electrically connected to at least one ground pad, although the top substrate pads 104 are not shown in the remaining figures for simplicity's sake.

As also shown in FIG. 3A, trench 128 (see also FIGS. 3B and 3C) forms interior side walls 130 to separate (top left) mold body portion 122 from (top right) mold body portion 222, and also forms interior side walls 130 to separate (bottom left) mold body portion 136 from (bottom right) mold body portion 322. Trench 328 (see also FIG. 3D) forms interior side walls 130 to separate (top left) mold body portion 122 from (bottom left) mold body portion 136, and also forms interior side walls 130 to separate (top right) mold body portion 222 from (bottom right) mold body portion 322. It is noted that the description of “top”, “bottom”, “left,” and “right” given in parentheses herein indicate the location of the respective mold body portion relative to the respective package plan view.

Top surfaces, interior side walls, and exterior side walls of each mold body portion 122, 222, and 322 are respectively covered with shielding layers 334, 336, and 338 to form three shielded compartments in which electronic components are isolated from the antenna module 112, as well as from one another and from the external environment. Shielding layers 334, 336, and 338 each make electrical contact with both conductive traces 110 and 310 in the trenches 128 and 328. Mold body portion 136, which includes antenna module 112, remains unshielded (e.g., no shielding layer is deposited over the top surface, interior side walls, and exterior side walls of portion 136). Shielding layers 334, 336, and 338 may be formed during a single sputtering process or other suitable deposition process.

As shown in FIG. 3B, mold body portion 122 includes an SMD 118, and mold body portion 222 includes an SMD 118 and another electronic component 320 having two or more pins attached to respective top substrate pads 104. As shown in FIG. 3C, mold body portion 322 includes a flip chip die 316 having a plurality of pins or solder bumps attached to respective top substrate pads 104 of package substrate 102. Mold body portion 136 includes antenna module 112, which remains unshielded. As shown in FIG. 3D, mold body portion 122 includes another SMD 118. A ground plane (e.g., ground plane 108 or 308) may also be included underneath one or more of mold body portions 122, 222, and 322 to provide additional shielding, which does not extend underneath antenna module 112. Such a ground plane may not reach the outer edge of the package substrate 102 in the embodiment shown, while such a ground plane may make electrical contact with a respective shielding layer at the outer edge of the package substrate 102 in other embodiments (e.g., FIG. 1B).

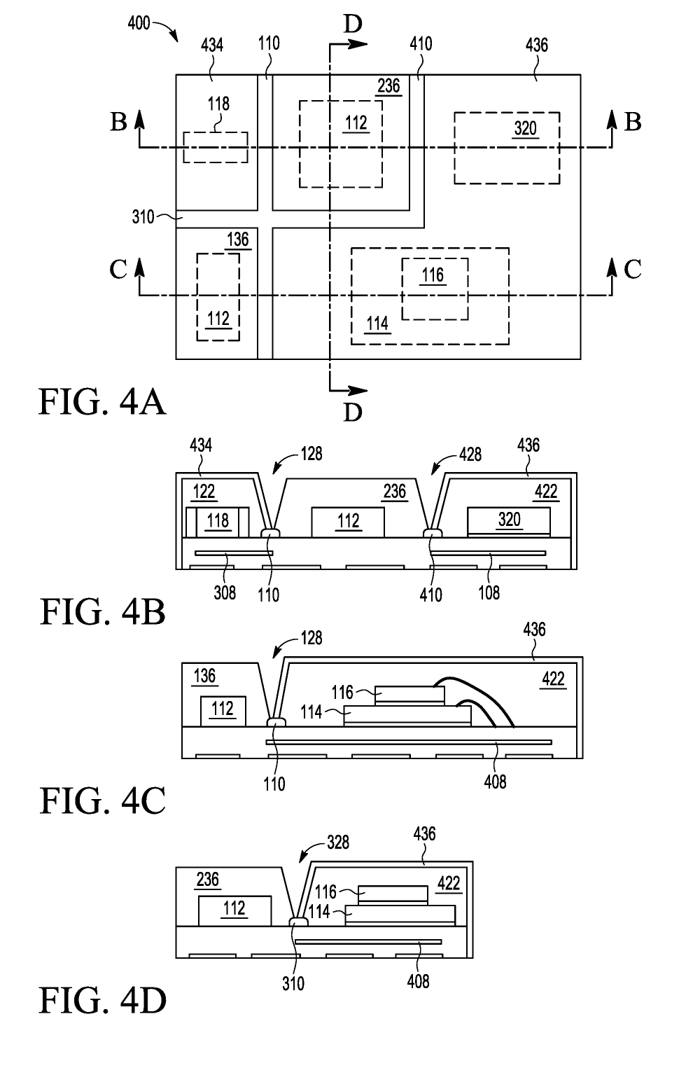

FIG. 4A shows a plan view, and FIGS. 4B, 4C, and 4D show representative cross-sectional views, of another example packaged semiconductor device 400 (or package 400) having selective shielding to form two shielded compartments with two unshielded antenna modules between the shielded compartments. Package 400 includes four mold body portions 136, 236, 122, and 422 that are separated from one another by three trenches that follow and expose perpendicular conductive traces. As shown in FIG. 4A, conductive trace 110 extends from a first (top) edge to an opposite second (bottom) edge of the package substrate 102, and conductive trace 310 extends from a third (left) edge toward a fourth (right) edge of the package substrate 102. However, in the embodiment shown in FIG. 4A, conductive trace 310 does not reach the fourth edge of the package substrate 102. Rather a third conductive trace 410 extends from the end point of conductive trace 310 and reaches back to the first (top) edge of the package substrate, where conductive trace 410 is parallel with conductive trace 110. Conductive traces 110, 310, and 410 are electrically connected to at least one ground pad, although top substrate pads 104 are not shown in FIG. 4A through 4D for simplicity's sake.

As also shown in FIG. 4A, trench 128 (see also FIGS. 4B and 4C) forms interior side walls to separate (top left) mold body portion 122 from (top center) mold body portion 236, and forms interior side walls to separate (bottom left) mold body portion 136 from (right) mold body portion 422. Trench 328 (see also FIG. 4D) forms interior side walls to separate (top left) mold body portion 122 from (bottom left) mold body portion 136, and to form interior side walls to separate (top center) mold body portion from (lower right) mold body portion 422. Trench 428 (see also FIG. 4B) forms interior side walls to separate (top center) mold body portion from (right) mold body portion 422.

Top surfaces, interior side walls, and exterior side walls of each mold body portion 122 and 422 are respectively covered with shielding layers 434 and 436 to form two shielded compartments in which electronic components are isolated from the antenna modules 112, as well as from one another and from the external environment. Shielding layer 434 makes electrical contact with both conductive traces 110 and 310, while shielding layer 436 makes electrical contact with conductive traces 110, 310, and 410. Mold body portions 136 and 236 that each include an antenna module 112 remain unshielded. Shielding layers 434 and 436 may be formed during a single sputtering process or other suitable deposition process. A ground plane (e.g., ground plane 108, 308, or 408) may also be included underneath one or more of mold body portions 122 and 422 to provide additional shielding, which does not extend underneath either antenna module 112. Such a ground plane may not reach the outer edge of the package substrate 102 in the embodiment shown, while such a ground plane may make electrical contact with a respective shielding layer at the outer edge of the package substrate 102 in other embodiments (e.g., FIG. 1B.

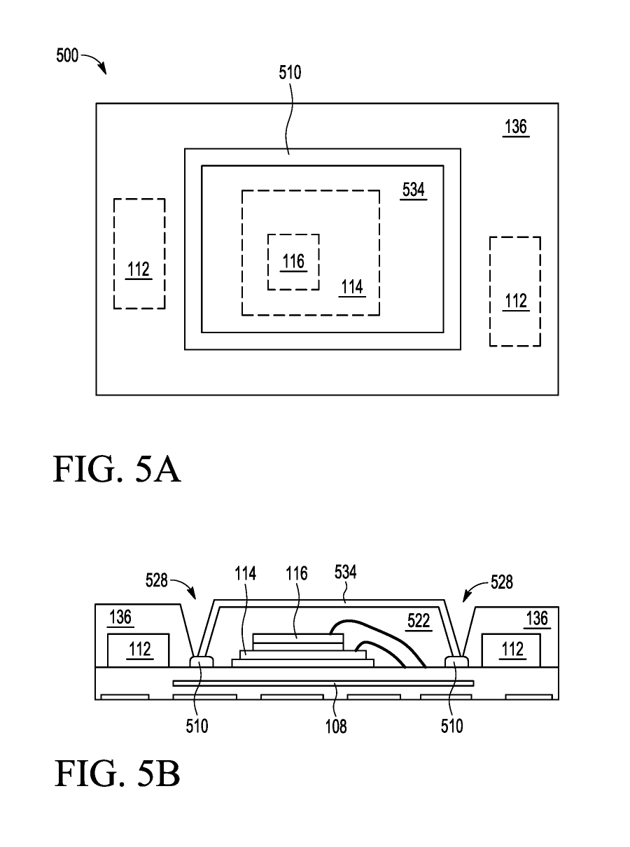

FIG. 5A shows a plan view, and FIG. 5B shows a representative cross-sectional view, of another example package semiconductor device 500 (or package 500) having a center shielded compartment, while antenna module(s) near the outer edge(s) of the package 500 remain unshielded. Package 500 includes an inner or center mold body portion 522 and an outer mold body portion 136 that surrounds the inner mold body portion 522. Mold body portions 522 and 136 are separated from one another by a trench 528 that has a closed loop form, which follows a conductive trace 510 that also has a closed loop form. As shown in FIG. 5A, conductive trace 510 is formed to have a rectangular path that surrounds the inner mold body portion 522. In other embodiments, conductive trace 510 may be formed to have differently shaped closed loop paths as needed, such as triangular, polygonal, circular, oblong, and the like. Conductive trace 510 is electrically connected to at least one ground pad.

Trench 528 forms interior side walls to separate the inner mold body portion 522 from the outer mold body portion 136. The top surface and interior side walls of the inner mold body portion 522 are covered with shielding layer 534, which makes electrical contact with conductive trace 510 around inner mold body portion 522, forming a center shielded compartment. Outer mold body portion 136 that includes antenna module(s) 112 remains unshielded. A ground plane 108 may also be included underneath the inner mold body portion 136 to provide additional shielding.

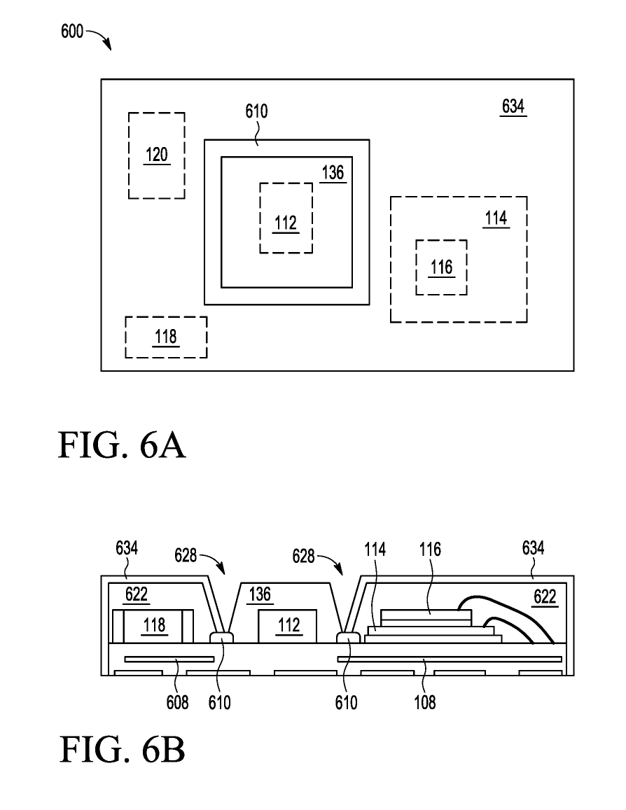

FIG. 6A shows a plan view, and FIG. 6B shows a representative cross-sectional view, of another example package semiconductor device 600 (or package 600) having an outer shielded compartment, while an antenna module near the center of the package 600 remains unshielded. Package 600 includes an inner mold body portion 136 and an outer mold body portion 622 that surrounds the inner mold body portion 136. Mold body portions 136 and 622 are separated from one another by a trench 628 that has a closed loop form, which follows a conductive trace 610 that also has a closed loop form similar to that shown in FIG. 5A, which may have different shaped paths in other embodiments.

Trench 628 forms interior side walls to separate the inner mold body portion 136 from the outer mold body portion 522. The top surface, interior side walls, and exterior side walls of the outer mold body portion 522 are covered with shielding layer 634, which makes electrical contact with conductive trace 610, forming an outer shielded compartment. A ground plane 108 may also be included underneath the outer mold body portion 522 to provide additional shielding.

FIGS. 7, 8, 9, 10, 11, 12A, 12B, 13A, 13B, 13C, 14A, and 14B show various representative steps of a fabrication process in which the present disclosure is implemented. It is noted that these figures show fabrication of an example package, and that the fabrication steps discussed herein may be used to fabricate any other packages that implement the present disclosure. It is also noted that the individual substrate shown in FIG. 7 through 10 may be representative of a number of substrates formed as part of an array or strip of substrates that are then singulated to form a number of packages, as shown in FIG. 11.

FIG. 7 shows a package substrate 102 having a plurality of top surface pads and bottom surface pads. It is noted that the top and bottom surface pads are presently shown as being distributed in a uniform pitch across the top and bottom surfaces of package substrate 102, which is merely intended to be representative of general pad placement. The top and bottom surface pads may be placed according to a layout defined for the specific components to be included in the package. For simplicity's sake, the top surface pads are omitted from the remaining figures. Package substrate 102 may optionally include a ground plane that underlies the area in which a shielded compartment is formed, as shown below.

FIG. 8 shows a number of electronic components attached to the top surface of the package substrate 102, such as an antenna module 112, one or more die (e.g., 114 and 116), an SMD 118, which are representative of any combination of electronic components that may be included in the package. Appropriate wire bonds 132 may also be formed to electrically connect bond pads of some electronic components to the top surface pads of the package substrate 102, while other electronic components may have pins that are directly electrically connected to the top surface pads of the package substrate 102. Conductive trace 110 is also formed, such as by sintering, printing, depositing, and the like. In some embodiments, conductive trace 110 may be formed as part of package substrate 102 and exposed in the top surface of the package substrate 102.

FIG. 9 shows package substrate 102 overmolded with a mold compound to form a mold body 122 that encapsulates the electronic components. FIG. 10 shows a trench 128 formed in a top surface of the mold body 122 to expose the conductive trace 110 and to separate the mold body 122 into two or more mold body portions (e.g., portions 122 and 136). Trench 128 may be formed by a cutting technique, such as sawing, etching, laser cutting, and the like. In embodiments using a cutting technique, it may be beneficial to have a much taller or thicker conductive trace 110 to provide a buffer, allowing the trench 128 to reach the top surface of the conductive trace 110 without damaging the underlying package substrate 102. In other embodiments, the mold body portions may be directly formed using film assisted molding that uses a plunger member directly over the conductive trace 110 to expose it without cutting a trench into the mold body.

FIG. 11 shows package substrate 102 as one of a number of package substrates in a strip or array 1102 of substrates, each having attached electronic components that have been overmolded and trenches formed. Singulation of the array 1102 is shown as openings 1106, which may be formed by sawing or other suitable singulation technique, to form a number of packages 1104. The singulation may also form exterior side walls of the mold body portions that are substantially aligned with respective outer edges of package substrate 102.

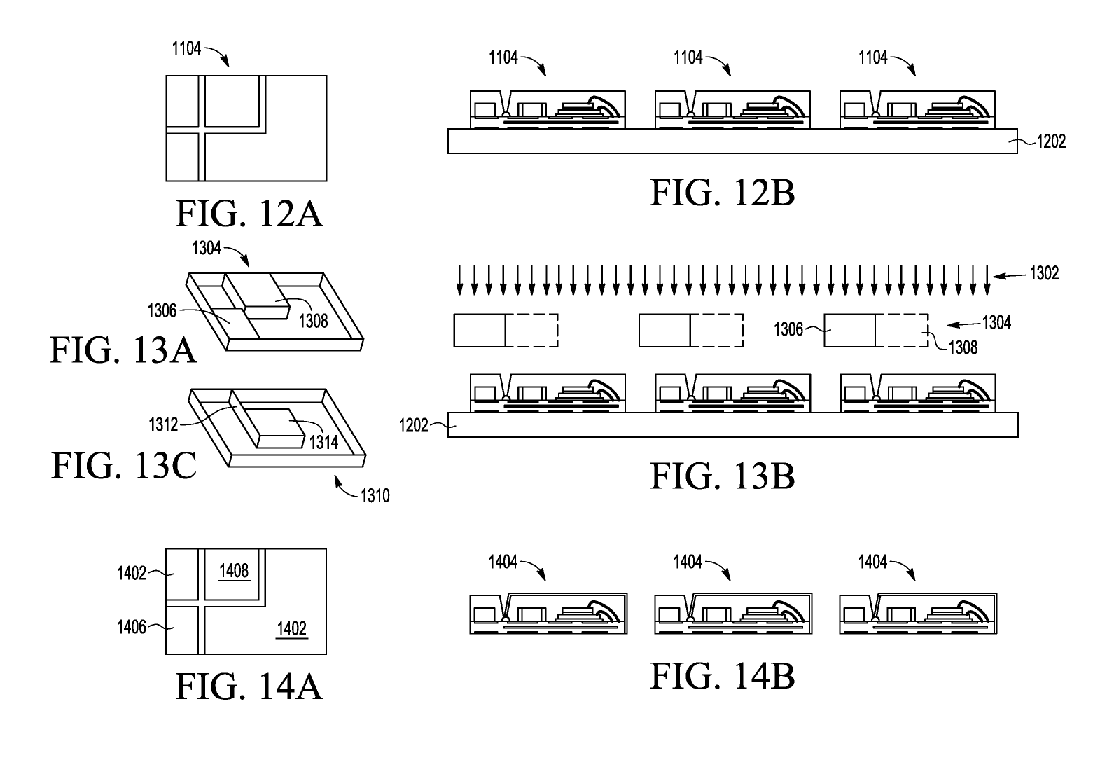

FIG. 12A shows a plan view of the example package 1104, which is similar to the plan view of FIG. 4A. Packages 1104 are attached with uniform pitch to an adhesive tape 1202, such as at a 1 mm pitch on a dicing tape. In some embodiments, adhesive tape 1202 is formed from a polymer film such as PVC (polyvinyl chloride), polyolefin, polyethylene, or similar material, where an adhesive is placed on a surface of the polymer film. In some embodiments, the adhesive tape 1202 is removable in response to UV (ultraviolet light) exposure or temperature excursion (e.g., the adhesive weakens in response to the UV exposure or temperature excursion). In some embodiments, adhesive tape 1202 includes a release layer to release the package from the adhesive tape 1202.

FIG. 13A shows a view of an example metal frame 1304 used in a sputtering process to deposit a conductive shielding layer on one or more mold body portions of the package 1104. Metal frame 1304 includes coverings 1306 and 1308, where the space on either side of the coverings 1306 and 1308 forms a window or cutout of the metal frame. Coverings 1306 and 1308 are aligned over the mold body portions that will remain unshielded, where the coverings 1306 and 1308 block any conductive material from being deposited on those mold body portions. FIG.13B shows placement of the metal frame 1304 over each package 1104. A conductive material is then deposited on to the packages 1104 through the metal frames 1304, where the conductive material passes through the cutout portions of the metal frame 1304 onto the targeted mold body portions to form a conformal shielding layer over the top surfaces and (interior and exterior) side walls of the targeted mold body portions, resulting in shielded compartments of the package 1104. FIG. 14A shows a plan view of the resulting package 1404, which is similar to that shown in FIG. 4A. In the embodiment shown, each package 1404 includes shielded compartments 1402, and unshielded portions 1406 and 1408, which may include an antenna module. The electronic components included in each shielded compartment are isolated from the antenna module, as well as from the external environment. The electronic components in neighboring shielded compartments are also isolated from one another. FIG. 14B shows the resulting packages 1404 are removed from tape 1202. In some embodiments, the packages 1404 may be subsequently placed in shipping trays.

FIG. 13C shows a view of another example metal frame 1310 used in a sputtering process. Metal frame 1310 includes a center covering 1314 that is connected to the outer frame by an arm or bar 1312. Bar 1312 should be large enough to accommodate the weight of the center covering, but thin enough to allow sputtering of the conductive shielding layer onto the underlying mold body portion without forming a “shadow” or absence of conductive shielding layer onto the underlying mold body portion. The resulting package 1104 using metal frame 1310 is similar to that shown in FIG. 6A.

By now it should be appreciated that a shielding solution has been provided that separates a mold body into several portions, one of which includes an embedded antenna, and a conductive shielding layer is deposited over mold body portions that include other electronic components to isolate them from the embedded antenna. The conductive shielding layer effectively covers and seals the mold body portions down to a conductive trace that is conformal to the top surface of the substrate, providing improved shielding and isolation of the embedded electronic components.

In one embodiment of the present disclosure, a packaged semiconductor device is provided, the device including: a substrate; an antenna module attached to a top surface of the substrate, the antenna module including an antenna; an electronic component attached to the top surface of the substrate, the electronic component communicatively coupled to the antenna module through electrical connections in the substrate; a first portion of mold body that encapsulates the antenna module; a second portion of mold body that encapsulates the electronic component, wherein the second portion of mold body is separated from the first portion of mold body by at least a first trench; and a shielding layer that covers the second portion of mold body.

One aspect of the above embodiment provides that the packaged semiconductor device further includes: a conductive trace on the top surface of the substrate and under the first trench, wherein the conductive trace follows a path formed by the first trench, the conductive trace makes direct contact with at least one ground contact pad, and the shielding layer directly contacts the conductive trace that is exposed in the first trench.

A further aspect of the above embodiment provides that the shielding layer further directly contacts a side wall of the second portion of mold body formed by the first trench and a top surface of the second portion of mold body.

A still further aspect of the above embodiment provides that the side wall of the second portion is angled with a positive slope from the conductive trace to the top surface of the second portion of mold body.

Another further aspect of the above embodiment provides that the shielding layer further directly contacts at least one external side wall of the second portion of mold body, the at least one external side wall of the second portion of mold body is coplanar with at least one external side wall of the substrate, and the shielding layer further directly contacts the at least one external side wall of the substrate.

Another aspect of the above embodiment provides that the substrate includes a ground plane located beneath the second portion of mold body.

Another aspect of the above embodiment provides that the electronic component includes one of a semiconductor die, a flip chip die, a surface mount device, a memory module, and an integrated circuit.

Another aspect of the above embodiment provides that the first trench follows a path that begins from an external side wall of the substrate and ends at another external side wall of the substrate.

Another aspect of the above embodiment provides that the first trench includes one or more trench segments, the first trench follows a path that begins and ends at a same external side wall of the substrate.

Another aspect of the above embodiment provides that the packaged semiconductor device further includes: a third portion of mold body that encapsulates another antenna module attached to the top surface of the substrate, wherein the third portion is separated from the second portion of mold body by at least a second trench.

Another aspect of the above embodiment provides that the packaged semiconductor device further includes: a third portion of mold body that encapsulates another electronic component attached to the top surface of the substrate, wherein the third portion is separated from the first portion of mold body by at least a second trench, and the shielding layer further covers the third portion of mold body.

Another aspect of the above embodiment provides that the packaged semiconductor device further includes: a third portion of mold body that encapsulates another electronic component attached to the top surface of the substrate, wherein the third portion is separated from the second portion of mold body by at least a second trench, and the shielding layer further covers the third portion of mold body.

A further aspect of the above embodiment provides that the shielding layer directly contacts side walls of the second and third portions of mold body formed by the second trench.

In another embodiment of the present disclosure, a packaged semiconductor device is provided, the device including: a substrate; a first portion of mold body that encapsulates an antenna module attached to a top surface of the substrate, the antenna module including an antenna; a second portion of mold body that encapsulates at least one electronic component attached to the top surface of the substrate, the second portion of mold body surrounding the first portion of mold body, the second portion of mold body separated from the first portion of mold body by a trench that follows a closed path around the first portion of mold body; and a shielding layer that covers the second portion of mold body, wherein the first portion of mold body that encapsulates the antenna module is not covered by the shielding layer.

One aspect of the above embodiment provides that the packaged semiconductor device further includes: a conductive trace on the surface of the substrate that follows the closed path around the first portion of mold body, wherein the conductive trace makes direct contact with at least one ground contact pad, and the shielding layer directly contacts the conductive trace that is exposed in the trench.

Another aspect of the above embodiment provides that the shielding layer directly contacts inner side walls of the second portion formed by the trench, a top surface of the second portion of mold body, and external side walls of the second portion of mold body.

Another aspect of the above embodiment provides that the shielding layer further directly contacts external side walls of the substrate.

Another aspect of the above embodiment provides that the substrate includes a ground plane located beneath the second portion of mold body.

In another embodiment of the present disclosure, a packaged semiconductor device is provided, the device including: a substrate; a first portion of mold body that encapsulates at least one electronic component attached to a top surface of the substrate; a second portion of mold body that encapsulates at least one antenna module attached to the top surface of the substrate, each of the at least one antenna module including an antenna, the second portion of mold body surrounding the first portion of mold body, the second portion of mold body separated from the first portion of mold body from the second portion of mold body by a trench that follows a closed path around the first portion of mold body; and a shielding layer that covers the first portion of mold body, wherein the second portion of mold body that encapsulates the at least one antenna module is not covered by the shielding layer.

One aspect of the above embodiment provides that the packaged semiconductor device further includes: a conductive trace on the surface of the substrate that follows the closed path around the first portion of mold body, wherein the conductive trace makes direct contact with at least one ground contact pad, and the shielding layer directly contacts the conductive trace that is exposed in the trench.

Because the apparatus implementing the present invention is, for the most part, composed of electronic components and circuits known to those skilled in the art, circuit details will not be explained in any greater extent than that considered necessary as illustrated above, for the understanding and appreciation of the underlying concepts of the present invention and in order not to obfuscate or distract from the teachings of the present invention.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

It is noted that the term “neighboring” as used herein means “adjacent to” (e.g., next to and without an intervening object), and “laterally” as used herein means “in a sideways direction” (e.g., a horizontal direction that is parallel to a plane of the substrate).

As used herein, the terms “substantial” and “substantially” mean sufficient to achieve the stated purpose or value in a practical manner, taking into account any minor imperfections or deviations, if any, that arise from usual and expected process abnormalities that may occur during package fabrication, which are not significant for the stated purpose or value.

The following description refers to nodes or features being “connected” or “coupled” together. As used herein, unless expressly stated otherwise, “coupled” means that one node or feature is directly or indirectly joined to (or is in direct or indirect communication with) another node or feature, and not necessarily physically. As used herein, unless expressly stated otherwise, “connected” means that one node or feature is directly joined to (or is in direct communication with) another node of feature. Furthermore, although the various schematics shown herein depict certain example arrangements of elements, additional intervening elements, devices, features, or components may be present in an actual embodiment (assuming that the functionality of the given circuit is not adversely affected).

Although the invention is described herein with reference to specific embodiments, various modifications and changes can be made without departing from the scope of the present invention as set forth in the claims below. For example, additional or fewer shielded compartments may be implemented in FIG. 1A. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

The term “coupled,” as used herein, is not intended to be limited to a direct coupling or a mechanical coupling.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

1. A packaged semiconductor device comprising:
a substrate;
an antenna module attached to a top surface of the substrate, the antenna module comprising an antenna;
an electronic component attached to the top surface of the substrate, the electronic component communicatively coupled to the antenna module through electrical connections in the substrate;
a first portion of mold body that encapsulates the antenna module;
a second portion of mold body that encapsulates the electronic component, wherein the second portion of mold body is separated from the first portion of mold body by at least a first trench;
a conductive trace formed on the top surface of the substrate and under the first trench, wherein
the conductive trace follows an entire path of the first trench, and
the conductive trace makes direct contact with at least one ground contact pad; and
a shielding layer that covers the second portion of mold body, wherein
the shielding layer directly contacts a portion of the conductive trace that is exposed in the first trench.

2. (canceled)

3. The packaged semiconductor device of claim 1, wherein the shielding layer further directly contacts a side wall of the second portion of mold body formed by the first trench and a top surface of the second portion of mold body.

4. The packaged semiconductor device of claim 3, wherein the side wall of the second portion is angled with a positive slope from the conductive trace to the top surface of the second portion of mold body.

5. The packaged semiconductor device of claim 1, wherein the shielding layer further directly contacts at least one external side wall of the second portion of mold body, the at least one external side wall of the second portion of mold body is coplanar with at least one external side wall of the substrate, and the shielding layer further directly contacts the at least one external side wall of the substrate.

6. The packaged semiconductor device of claim 1, wherein the substrate comprises a ground plane located beneath the second portion of mold body.

7. The packaged semiconductor device of claim 1, wherein the electronic component comprises one of a semiconductor die, a flip chip die, a surface mount device, a memory module, and an integrated circuit.

8. The packaged semiconductor device of claim 1, wherein the first trench follows a path that begins from an external side wall of the substrate and ends at another external side wall of the substrate.

9. The packaged semiconductor device of claim 1, wherein the first trench includes one or more trench segments, the first trench follows a path that begins and ends at a same external side wall of the substrate.

10. The packaged semiconductor device of claim 1, further comprising:
a third portion of mold body that encapsulates another antenna module attached to the top surface of the substrate, wherein the third portion is separated from the second portion of mold body by at least a second trench.

11. The packaged semiconductor device of claim 1, further comprising:
a third portion of mold body that encapsulates another electronic component attached to the top surface of the substrate, wherein the third portion is separated from the first portion of mold body by at least a second trench, and the shielding layer further covers the third portion of mold body.

12. The packaged semiconductor device of claim 1, further comprising:
a third portion of mold body that encapsulates another electronic component attached to the top surface of the substrate, wherein the third portion is separated from the second portion of mold body by at least a second trench, and the shielding layer further covers the third portion of mold body.

13. The packaged semiconductor device of claim 12, wherein the shielding layer directly contacts side walls of the second and third portions of mold body formed by the second trench.

14. A packaged semiconductor device comprising:
a substrate;
a first portion of mold body that encapsulates an antenna module attached to a top surface of the substrate, the antenna module comprising an antenna;
a second portion of mold body that encapsulates at least one electronic component attached to the top surface of the substrate, the second portion of mold body surrounding the first portion of mold body, the second portion of mold body separated from the first portion of mold body by a trench that follows a closed path around the first portion of mold body; and
a shielding layer that covers the second portion of mold body, wherein the first portion of mold body that encapsulates the antenna module is not covered by the shielding layer.

15. The packaged semiconductor device of claim 14, further comprising:
a conductive trace on the surface of the substrate that follows the closed path around the first portion of mold body, wherein
the conductive trace makes direct contact with at least one ground contact pad, and
the shielding layer directly contacts the conductive trace that is exposed in the trench.

16. The packaged semiconductor device of claim 14, wherein the shielding layer directly contacts inner side walls of the second portion formed by the trench, a top surface of the second portion of mold body, and external side walls of the second portion of mold body.

17. The packaged semiconductor device of claim 14, wherein the shielding layer further directly contacts external side walls of the substrate.

18. The packaged semiconductor device of claim 14, wherein the substrate comprises a ground plane located beneath the second portion of mold body.

19. A packaged semiconductor device comprising:
a substrate;
a first portion of mold body that encapsulates at least one electronic component attached to a top surface of the substrate;
a second portion of mold body that encapsulates at least one antenna module attached to the top surface of the substrate, each of the at least one antenna module comprising an antenna, the second portion of mold body surrounding the first portion of mold body, the second portion of mold body separated from the first portion of mold body from the second portion of mold body by a trench that follows a closed path around the first portion of mold body; and
a shielding layer that covers the first portion of mold body, wherein the second portion of mold body that encapsulates the at least one antenna module is not covered by the shielding layer.

20. The packaged semiconductor device of claim 19, further comprising:
a conductive trace on the surface of the substrate that follows the closed path around the first portion of mold body, wherein
the conductive trace makes direct contact with at least one ground contact pad, and
the shielding layer directly contacts the conductive trace that is exposed in the trench.

21. The packaged semiconductor device of claim 1, wherein
the conductive trace has a height that is greater than any trace formed as part of the substrate.
